(19) United States
(12) Patent Application Publication
(10) Pub. No.: US 2017/0092484 A1
(43) Pub. Date: Mar. 30, 2017

(54) METHOD AND APPARATUS FOR DRYING SEMICONDUCTOR SUBSTRATES USING LIQUID CARBON DIOXIDE

(71) Applicant: Tokyo Electron Limited, Tokyo (JP)

(72) Inventors: Ian J. Brown, Portland, OR (US); Wallace P. Printz, Austin, TX (US); Antonio Luis Pacheco Rotondaro, Austin, TX (US); Gentaro Goshi, Kumamoto (JP); Keisuke Egashira, Kumamoto (JP)

(21) Appl. No.: 15/281,955

(22) Filed: Sep. 30, 2016

Related U.S. Application Data
(60) Provisional application No. 62/235,126, filed on Sep. 30, 2015.

(51) Int. Cl. H01L 21/02; B08B 3/10; C11D 11/00; H01L 21/687; H01L 21/67; C11D 7/04; B08B 3/08; H01L 21/324

(52) U.S. Cl. CPC H01L 21/02057; B08B 3/08; B08B 3/102; H01L 21/324; H01L 21/68764; H01L 21/67028; C11D 7/04; C11D 11/0047

(57) ABSTRACT

Method and apparatus for rinsing and drying a semiconductor substrate having a first rinse liquid such as water on the substrate in a substrate processing system. The method includes dispensing onto the substrate liquid carbon dioxide to displace any liquid present on the substrate and to dry the substrate. The apparatus includes a chamber for rinsing and drying the substrate.

This application claims priority to U.S. provisional application Ser. No. 62/235,126, filed Sep. 30, 2015, incorporated by reference in its entirety.

### TECHNICAL FIELD OF THE INVENTION

This invention relates to wet treatment of semiconductor surfaces. More specifically, it provides a novel method for drying semiconductor surfaces, an apparatus for implementing the proposed method, and related methods.

### BACKGROUND

Drying of a semiconductor surface involves the removal of water, an aqueous solution, a solvent, an organic solution, any other processing liquid that was used to treat the semiconductor surface, or any mixture of two or more thereof. The drying process should result in a pristine semiconductor surface free of the processing liquid without damaging any of the surface features. Supercritical carbon dioxide (sc-CO2) has been proposed for use in drying semiconductor surfaces. In such processes, for example, water on a substrate is displaced with isopropyl alcohol, the substrate is then treated with sc-CO2 followed by purging of the drying chamber, and then the chamber is purged with fresh sc-CO2 a number of times, followed by venting the chamber to the atmosphere. While sc-CO2 has no surface tension and thus limits structural damage of the semiconductor surface during a drying process, the equipment needed to enable use of sc-CO2 is unduly heavy and expensive to permit the high pressures required to achieve sc-CO2. For example, equipment cost is sensitive to pressure rating (wall thickness, safety regulations, and so on), sc-CO2 does not absorb water well thus requiring co-solvents such as isopropyl alcohol or ethanol to enhance water uptake, and heating is needed during pressure drop to avoid isopropyl alcohol and water to rain down on the substrate or condensation of water marks after leaving the drying chamber.

### SUMMARY OF THE INVENTION

This invention provides a solution to one or more of the disadvantages and shortcomings described above.

In one broad respect, an embodiment of the invention solves the challenging problem of removing a processing liquid from a semiconductor surface without leaving any residues and/or watermarks on the semiconductor surface and without causing any damage to any of the features on the semiconductor surface. With the scaling of dimensions on the semiconductor integrated circuits, as is known the forces exerted based on surface tension and contact angle on the features present on the semiconductor surface during the drying process have increased and, if non-optimized drying processes are used, can result in the collapse of the features.

An embodiment of the invention uses liquid carbon dioxide (Liq-CO₂) to displace the processing fluid from the semiconductor surface and subsequently controllably volatilizes the Liq-CO2 from the semiconductor surface without leaving any residues and/or watermarks and without causing any damage to the features present on the semiconductor surface. While not as low as sc-CO2, the extremely low surface tension of the Liq-CO₂ allows for a drying process without pattern collapse. The surface tension of liq-CO2 is approximately 10 times less than that of isopropyl alcohol, the latter being a common solvent used in semiconductor processing. Liquid CO2 is capable of penetrating semiconductor surface structures to remove material. Liquid CO2 has the same capability as sc-CO2 to displace fluids but while operating at lower pressures and temperatures. However, co-solvents can be used in conjunction with liquid CO2, which increases liquid density at lower pressure or higher temperature. Accordingly, a liquid CO2 drying process reduces complexity of system design, reduces manufacturing costs relative to sc-CO2 while permitting equivalent drying performance at equal density. Furthermore, a liquid CO2 drying process may decrease process defects because unlike sc-CO2, liquid CO2 does not extract oils and hydrocarbons from system seals, o-rings, valves, and so on, which would have the potential to contaminate the process. Advantageously, liquid CO2 has a surface tension which is believed to be sufficiently low to avoid pattern collapse on a semiconductor substrate.

Thus in one broad respect, this invention is a method for rinsing and drying a substrate in a substrate processing system, comprising: dispensing a first rinse liquid onto the substrate; and dispensing onto the substrate liquid carbon dioxide (CO₂), to displace any liquid present on the substrate and to dry the substrate.

A further embodiment also provides an apparatus for Liquid Carbon Dioxide processing of the semiconductor surface enabling the removal of any fluid that was present on the semiconductor surface without leaving any residue and/or watermarks and without causing any damage to the features present on the semiconductor surface. Thus in another broad respect, this invention is a substrate processing system, comprising: a processing chamber having a substrate support, the processing chamber being configured for dispensing liquid carbon dioxide (CO₂) onto the substrate; a source of liquid CO₂ for supplying liquid CO₂ to the processing chamber; and a transfer system for transferring the substrate to and from the processing chamber, and/or transferring the substrate to and from the substrate processing system.

In another broad respect, this invention is a method of manufacturing an apparatus for liquid carbon dioxide processing of a semiconductor surface, which comprises providing a processing chamber having a substrate support, the processing chamber being configured for dispensing liquid carbon dioxide (CO₂) onto the substrate; providing a source of liquid CO₂ for supplying liquid CO₂ to the processing chamber; and providing a transfer system for transferring the substrate to and from the processing chamber, and/or transferring the substrate to and from the substrate processing system.

The low processing temperature and pressure required for Liq-CO₂ processing provides a wider process latitude compared to other solutions, including sc-CO2. Moreover, this invention alleviates the requirements on the processing equipment such as pumps, gaskets, fittings, piping, chamber material, welding, and other items, with a significant equipment fabrication cost reduction. The operation point of pressure and temperature of the Liq-CO₂ process also significantly reduce chamber and equipment parts corrosion.

Drying semiconductor substrates in liquid carbon dioxide provides a drying process that uses pressures below the critical point of carbon dioxide leading to significant reduction in hardware cost and complexity. Liquid CO₂ is supplied in gas bottle, typically at 5000-6000 kPa. Thus, the apparatus and process of this invention employ equipment which can withstand pressures which enable the carbon dioxide to remain liquid when applied to the semiconductor substrate to be dried.

The ability of liquid CO₂ fluid to penetrate structures and remove materials is a function of its density. In an embodiment of the invention, the same density of Liquid CO₂ can be achieved as it has been used for scCO₂ drying processes. Thus, liquid CO₂ has the same capability of displacing fluids as scCO₂, but operates at a lower pressure and temperature point.

### DESCRIPTION OF THE DRAWINGS

It is noted that the appended drawings illustrate only exemplary embodiments of the invention and are, therefore, not to be considered limiting of its scope, for the invention may admit to other equally effective embodiments.

FIG. 1 generally illustrates an apparatus 100 for drying a semiconductor substrate using liquid carbon dioxide.

### DETAILED DESCRIPTION OF THE INVENTION

A drying method for a semiconductor substrate, in accordance with an embodiment of the invention is described herein. In this regard, a semiconductor substrate is treated with a chemical solution; the semiconductor substrate is rinsed with deionized water (DIW); the liquid covering a surface of the semiconductor substrate is changed from the deionized water to a water soluble organic solvent (i.e. Isopropyl alcohol—IPA) by for example displacing the water with the IPA, the semiconductor substrate wet with the water soluble organic solvent is transferred to a drying chamber; the water soluble organic solvent on the semiconductor substrate is rinsed with liquid carbon dioxide; and the liquid carbon dioxide and the alcohol is discharged from the drying chamber.

Alternatively, the step which includes use of a water soluble organic solvent can be eliminated and the semiconductor substrate is transferred wet with DIW to the drying chamber, and subsequently the DIW is rinsed (substituted) with a mixture of liquid carbon dioxide and a water soluble organic solvent (i.e. IPA).

The process temperature in the drying chamber is kept lower than the boiling point of the water soluble solvent. The semiconductor substrate is transferred to an exit chamber with controlled ambient to prevent condensation on the semiconductor substrate surface. The exit chamber has heating capability to bring the semiconductor substrate temperature to room temperature.

It should be appreciated that adding co-solvent to scCO2 makes the critical point harder to achieve, thus, it is easy to operate at Liq-CO2 compared to scCO2. Moreover, adding a solvent to liquid CO2 increases its density at lower pressure or higher temperature expanding the processing window of the Liq-CO2 process.

Even though the surface tension of Liq-CO2 is not zero, it is approximately ten times lower than the surface tension of IPA. Thus, the present invention permits drying with sufficiently low surface tension which avoids pattern collapse on the semiconductor substrate.

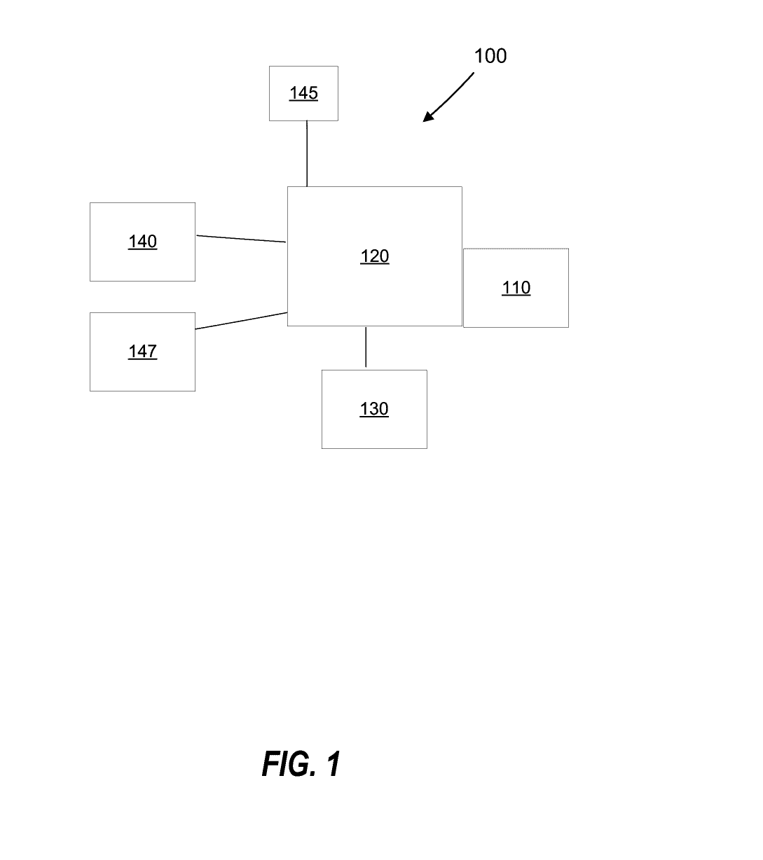

Turning to FIG. 1, there is shown an embodiment which includes an apparatus 100 for liquid carbon dioxide processing of semiconductor substrates. The apparatus includes a transfer module 110 having an entrance and a liquid carbon dioxide processing module 120 coupled to the transfer module. The process module 120 is configured to perform liquid carbon dioxide processing on a semiconductor substrate in a cavity having a substantially constant volume. The apparatus includes a liquid carbon dioxide source 130 which can be referred to as a condition generator, coupled to the processing module cavity. The liquid carbon dioxide source is able to supply liquid carbon dioxide to the processing module cavity and to recycle the liquid carbon dioxide with organic solvent that is discharged from the processing module cavity. The apparatus 100 includes a transfer mechanism 110 coupled to the transfer module. The transfer mechanism is configured to move the semiconductor substrate between the entrance and the liquid carbon dioxide processing module. The apparatus can include an ambient conditioning arrangement 140 coupled to the transfer module such that in operation the ambient conditioning arrangement maintains low humidity condition inside the transfer module and a wafer temperature above the module ambient dew point. The system 100 can include a wetting chamber 145 for dispensing a rinse liquid onto the substrate. Likewise, the system 100 can include an exit chamber 147 configured to receive the substrate temperature to reach ambient temperature or a temperature higher than the ambient dew point temperature, prior to removal of the substrate from the processing system 100. The exit chamber can include a heater for heating the substrate. The system 100 can include ultrasonic or other transducer built into the wall of the chamber 120, the transducer agitating the liquid carbon dioxide to promote mixing of the carbon dioxide with water, solvent, or both to enable drying of the substrate surface. The transducer or other agitation mechanism can be positioned at other positions in the system 100 to provide the agitation. The chambers and equipment are made and designed to contain the pressures to contain liquid carbon dioxide.

In operation, the apparatus 100 is used in a process that includes processing the semiconductor substrate with a chemical solution; rinsing the semiconductor substrate with deionized water; changing the liquid covering a surface of the semiconductor substrate from the deionized water to a water soluble organic solvent (i.e. Isopropyl alcohol—IPA); transferring the semiconductor substrate being wet with the water soluble organic solvent to a drying chamber; substituting the water soluble organic solvent on the semiconductor substrate with liquid carbon dioxide; and discharging the liquid carbon dioxide and the alcohol from the drying chamber. The amount of water used to rinse the substrate will vary depending on the type of substrate, amount of residue to be removed, and other conventional factors. The amount of liquid carbon dioxide used in this process can also vary depending on the amount of water and/or solvent to be removed. The amount of carbon dioxide could fill the chamber, but need not. The amount could fill the chamber, but need not. The amount of liquid carbon dioxide should be sufficient and effective to adequately remove the water and/or solvent.

In terms of process flow the process temperature in the drying chamber is kept lower than the boiling point of the solvent. The semiconductor substrate is transferred to an exit chamber with controlled ambient to prevent condensation on the semiconductor substrate surface.

Prior to introducing a substrate into the drying chamber, liquid CO2 can be dispensed into the chamber to cool the chamber. In addition, monitoring temperature and pressure in the drying chamber is useful to ensure a saturated condition is maintained during liquid CO2 introduction and flow. Also, heating after the liquid CO2 flow step facilitates avoidance of residual solvent raining onto the substrate. Mass transport of liquid CO2 into deionized water and/or solvent such as isopropyl alcohol can be enhanced by rotating the substrate while liquid CO2 is dispensed into the drying chamber, a shower head sprayer can be used for dispensing the liquid CO2 into the chamber, vibrational energy can be introduced into the system using an ultrasonic or magasonic transducer in the chamber wall, on the wafer arm holder, or inline with the liquid CO2 dispense stream, or combinations thereof.

In the following example, the apparatus was used that included a sealable chamber containing a substrate to be treated. The chamber was connected to a source of liquid carbon dioxide. In addition, the chamber had a conventional port equipped with a safety valve and pressure gauge, and which included a valve to allow exhaust of the chamber. The chamber including a cylindrical heater surrounding the cylindrical chamber, around which insulation was packed. Isopropyl alcohol could be manually introduced into the chamber prior to sealing the chamber and introduction of the liquid carbon dioxide. In this test, the “chip” sample test apparatus includes a liquid CO2 delivery system to a chip-holding apparatus such that the chip is immersed in liquid IPA solvent, liquid CO2 is supplied to the system from a compressed CO2 bottle, and the liq-CO2 is allowed to bleed out of the system through a needle valve. Heater and pressure sensors are used to monitor the temperature and pressure inside the chip test apparatus. During the chip testing practice, before the chip is added to the apparatus, liquid CO2 is purged through the system and the pressure cycled such that the test apparatus is brought to an initial cold state before the test begins. After the chip is added to the system, IPA is poured on top of the chip, the system is closed to atmosphere and liquid CO2 is supplied and slowly allowed to escape while fresh liq-CO2 is added to the system to maintain a high-pressure liquid condition. For testing, the chip is held immersed in the liquid CO2 puddle for a variable amount of time. Finally, the system jacket temperature is raised such that during the pressure release of CO2, the system temperature is maintained above the IPA condensation temperature and thus avoids any liquid IPA returned to the chip sample. In this manner, the mass of IPA is confirmed removed from the system by displacement with CO2 via the measurement of collapse condition on a SEM microscope. Seven random locations were evaluated using SEM on the test wafer. It was found that pattern collapse averaged a rate of 0.2%. It is believed this pattern collapse rate can be reduced by optimizing the apparatus and process conditions.

In the example, after addition of the liquid CO2 the heater is set to 220 C, which over time raises the internal chamber temperature from about 25 C to a maximum temperature below 100 C, specifically a temperature of about 90-95 C. The conditions are maintained so that the pressure is approximately 5.5 MPa.

Further modifications and alternative embodiments of this invention will be apparent to those skilled in the art in view of this description. It will be recognized, therefore, that the present invention is not limited by these example arrangements. Accordingly, this description is to be construed as illustrative only and is for the purpose of teaching those skilled in the art the manner of carrying out the invention. It is to be understood that the forms of the invention herein shown and described are to be taken as the presently preferred embodiments. Various changes may be made in the implementations and architectures. For example, equivalent elements may be substituted for those illustrated and described herein, and certain features of the invention may be utilized independently of the use of other features, all as would be apparent to one skilled in the art after having the benefit of this description of the invention.

What is claimed is:

1. A method for rinsing and drying a substrate having a first rinse liquid on the substrate in a substrate processing system, comprising:
dispensing onto the substrate liquid carbon dioxide (CO₂), to displace any liquid present on the substrate and to dry the substrate.

2. The method of claim 1, wherein the step of dispensing liquid CO₂ further comprises dispensing a second rinse liquid along with the liquid CO₂.

3. The method of claim 2, wherein the second rinse liquid comprises one or more organic solvents selected from the group consisted of isopropyl alcohol, ethanol, ketone, acetic acid, acetone, acetonitrile, 1-butanol, 2-butanol, 2-butanone, t-butyl alcohol, diethylene glycol, diethyl ether, diethylene glycol dimethyl ether (diglyme), 1,2-dimethoxy-ethane (glyme, DME), dimethyl-formamide (DMF), dimethyl sulfoxide (DMSO), 1,4-dioxane, ether, ethyl acetate, ethylene glycol, glycerin, hexamethylphosphoramide (HMPA), hexamethylphosphorous triamide (HMPT), methanol, methyl t-butyl ether (MTBE), N-methyl-2-pyrrolidinone (NMP), nitromethane, 1-propanol, 2-propanol, and tetrahydrofuran (THF).

4. The method of claim 2, wherein the temperature of the liquid CO₂ is less than the boiling temperature of the second rinse liquid.

5. The method of claim 1, further comprising:
dispensing a third rinse liquid onto the substrate prior to the step of dispensing the liquid CO₂.

6. The method of claim 5, wherein the temperature of the liquid CO₂ is less than the boiling temperature of the third rinse liquid.

7. The method of claim 6, wherein the third rinse liquid comprises one or more organic solvents selected from the group consisted of isopropyl alcohol, ethanol, ketone, acetic acid, acetone, acetonitrile, 1-butanol, 2-butanol, 2-butanone, t-butyl alcohol, diethylene glycol, diethyl ether, diethylene glycol dimethyl ether (diglyme), 1,2-dimethoxy-ethane (glyme, DME), dimethyl-formamide (DMF), dimethyl sulfoxide (DMSO), 1,4-dioxane, ether, ethyl acetate, ethylene glycol, glycerin, hexamethylphosphoramide (HMPA), hexamethylphosphorous triamide (HMPT), methanol, methyl t-butyl ether (MTBE), N-methyl-2-pyrrolidinone (NMP), nitromethane, 1-propanol, 2-propanol, and tetrahydrofuran (THF).

8. The method of claim 1, further comprising dispensing the first rinse liquid onto the substrate; wherein the first rinse liquid comprises deionized water.

9. The method of claim 8, wherein the steps of dispensing the first rinse liquid and dispensing the liquid CO₂ are performed in a same processing chamber.

10. The method of claim 8, wherein the step of dispensing the first rinse liquid is performed in a wetting chamber, and the step of dispensing liquid CO₂ is performed in a drying chamber separate from the wetting chamber.

11. The method of claim 1, further comprising:
transferring the substrate to an exit chamber prior to removal of the substrate from the substrate processing system.

12. The method of claim 1, further comprising:
heating the substrate to allow the substrate temperature to reach ambient temperature prior to removal of the substrate from the substrate processing system.

13. The method of claim 1, further comprising:
heating the substrate to allow the substrate temperature to reach a temperature higher than the ambient dew point temperature prior to removal of the substrate from the substrate processing system.

14. The method of claim 1, wherein the substrate is rotated on a substrate support during dispensing the first rinse liquid or dispensing the liquid CO₂, or both.

15. The method of claim 1, wherein the pressure of the liquid CO₂ is less than the critical pressure of CO₂.

16. The method of claim 1, wherein the temperature of the liquid CO₂ is from −50° C. to 30° C.

17. The method of claim 1, wherein the substrate comprises semiconductor devices, photo-voltaic (PV) devices, light-emitting diodes (LED), flat panel displays (FPD), or micro-electromechanical system (MEMS) devices.

18. The method of claim 1, wherein the step of dispensing onto the substrate liquid carbon dioxide (CO₂), further comprises:
agitating the liquid CO₂.

19. A substrate processing system, comprising:
a processing chamber having a substrate support, the processing chamber being configured for dispensing liquid carbon dioxide (CO₂) onto the substrate;
a source of liquid CO₂ for supplying liquid CO₂ to the processing chamber; and
a transfer system for transferring the substrate to and from the processing chamber, and for transferring the substrate to and from the substrate processing system.

20. A method of manufacturing a substrate processing system, comprising:
providing processing chamber having a substrate support, the processing chamber being configured for dispensing liquid carbon dioxide (CO₂) onto the substrate;
providing a source of liquid CO₂ for supplying liquid CO₂ to the processing chamber; and
providing a transfer system for transferring the substrate to and from the processing chamber, and for transferring the substrate to and from the substrate processing system.
